(19) United States
(12) Patent Application Publication
(10) Pub. No.: US 2024/0183736 A1
(43) Pub. Date: Jun. 6, 2024

(54) METHOD FOR MEASURING MECHANICAL SYSTEM PARAMETERS DESCRIBING AN ELECTRIC MOTOR SYSTEM

(71) Applicant: Danfoss Power Electronics A/S, Gråsten (DK)

(72) Inventor: Thomas Pichler, Nordborg (DK)

(21) Appl. No.: 18/527,556

(22) Filed: Dec. 4, 2023

(30) Foreign Application Priority Data
Dec. 5, 2022 (DE) 102022132234.3

(51) Int. Cl. G01M 1/10

(52) U.S. Cl. CPC G01M 1/10

(57) ABSTRACT

A method for measuring mechanical system parameters, in particular the moment of inertia and friction effects, describing an electric motor system, includes the steps of applying a linear ramp of electrical torque corresponding to a current slope h to the system; measuring data representative of the velocity response of the system; fitting the measured data with a model function by applying a curve fitting algorithm, wherein a number of fitting parameters coincides with the mechanical system parameters of the system. An electric motor system is further disclosed having an electric motor and a frequency converter or drive, wherein the electric motor system is provided for carrying out a corresponding method.

### CROSS-REFERENCE TO RELATED APPLICATION

This application claims foreign priority benefits under 35 U.S.C. § 119 from German Patent Application No. 102022132234.3, filed Dec. 5, 2022, the content of which is hereby incorporated by reference in its entirety.

### TECHNICAL FIELD

The present invention pertains to a method for measuring mechanical system parameters, in particular the moment of inertia and friction effects, describing an electric motor system. The method comprises the steps of
applying a linear ramp of electrical torque corresponding to a current slope h to the system,
measuring data representative of the velocity response of the system,
fitting the measured data with a model function by applying a curve fitting algorithm, wherein a number of fitting parameters coincides with the mechanical system parameters of the system.

The invention also pertains to an electric motor system comprising an electric motor and a frequency converter or drive, wherein the electric motor system is provided for carrying out a corresponding method.

### BACKGROUND

The invention applies to the operation of electric motors using frequency converters or drives. The invention may be applied in any industry using electric motors. Frequency converters drive electric motors in many applications. For high efficiency, precision and dynamics, the parameters describing the physical system of the electric motor have to be known.

These parameters typically have to be established manually by an operator, which may be a problem as it may introduce human errors and complicate the correct operation of the electric motor.

### SUMMARY

The aim of the present invention is to overcome this problem and to provide an improved method for autonomously or automatically establishing the mechanical system parameters of an electric motor system.

This aim is achieved by a method according to claim 1 and an electric motor system according to claim 10. Preferable embodiments of the invention are subject to the dependent claims.

According to claim 1, a method for measuring mechanical system parameters, in particular the moment of inertia and friction effects, describing an electric motor system is provided. The method comprises the steps of
applying a linear ramp of electrical torque corresponding to a current slope h to the system,
measuring data representative of the velocity response of the system,
fitting the measured data with a model function by applying a curve fitting algorithm, wherein a number of fitting parameters coincides with the mechanical system parameters of the system.

At its core, the invention proposes a method of applying a linear ramp of the electrical torque to the motor and measuring its velocity response. Based on a physical model of the system, the measured data is fitted with the model function. The fit result offers access to several unknown parameters after one single ramp.

The electric torque of an electric motor is proportional to the applied current. As the current can be controlled without knowledge of the mechanical parameters of the motor system, the method can be applied without a priori assumptions concerning all the mechanical parameters of the motor system. The current will then be ramped linearly from zero to a motor specific maximum. The motor will respond by accelerating, overcoming its inertia and friction effects.

The current ramp may be limited at a maximum velocity of the motor. The expected velocity response is modeled mathematically based on the physics of inertia, static friction, dynamic friction, viscous friction or any higher order of friction effects. The resulting model offers a function in terms of the velocity of the motor. Applying a curve fitting algorithm, the measured data points will be fitted accordingly. The number of unknown fitting parameters coincides with the unknown mechanical parameters of the system. The fit result will thus allow obtaining said parameters with an error estimate.

A natural expansion of this method is the inclusion of further unknown effects by repeating the measurement with different start conditions and compare the differences in the results. Some or all method steps may thus be carried out repeatedly, preferably with different start conditions, such as different motor speed, different system inertia etc.

The method allows measuring a number of mechanical characteristics, such as the moment of inertia and friction effects of the motor, using a single torque ramp. It also allows compensating unexpected and not modeled effects by repetition of the single ramp measurement. Generally, the invention helps driving electrification in various technical fields, increases energy efficiency and digitalization.

In a preferred embodiment of the invention, the linear ramp of electrical torque is applied by ramping an input current from zero to a motor specific maximum. The motor specific maximum may be input manually and/or may be stored at a drive driving the motor. The drive may comprise any storage, computation and power conversion devices required for driving the motor. The electric motor system may comprise the electric motor and the drive for driving the motor. The electric motor system may comprise any further components required for performing the presently described method.

In another preferred embodiment of the invention, the model function describing the mechanical system parameters is:

$$\\ \begin{matrix}\frac{d}{dt} ω = \frac{3}{2} ψ p \frac{{i}_{q}}{J} - \frac{{M}_{R}}{J} - \frac{{M}_{H}}{J} & ( 1.3 )\end{matrix}$$

wherein the force of friction and the static friction of the mechanical system yield a constant torque M_{R} and a threshold torque M_{H}, respectively.

In another preferred embodiment of the invention, the current slope h is chosen for a single ramp and a guess for the moment of inertia of the mechanical system is calculated by fitting the measured data with a quadratic equation f(x)=ax²+bx+c.

In another preferred embodiment of the invention, the moment of inertia is calculated from equation

$$J = \frac{3}{4} ψ h p \frac{1}{a} \qquad ( 1.6 )$$

In another preferred embodiment of the invention, the force of friction and the static friction of the mechanical system yield a constant torque M_{R} and a threshold torque M_{H} calculated from equations

$${M}_{R} = - \frac{3}{2} ψ {hpt}_{0} - bJ \qquad ( 1.7 )$$

$$and$$

$${M}_{H} = \vert \sqrt{{( \frac{3}{2} ψ {hpt}_{0} + {M}_{R} )}^{2} - c \cdot 3 J ψ h p} \qquad ( 1.8 )$$

In another preferred embodiment of the invention, the method is repeated with at least three different current slopes h, wherein the results are fitted with the power law f(x)=ax^{b}+c and the resulting offset c is the real value of the momentum of inertia.

In another preferred embodiment of the invention, the model function describing the mechanical system parameters is

$$\frac{d}{dt} ω = \frac{3}{2} ψ p \frac{ht}{J} - ( \frac{{M}_{R}}{J} - {Ae}^{- B ω ( t )} ) \qquad ( 2.1 )$$

wherein the force of friction of the mechanical system yields a constant torque M_{R} and wherein the general solution of this differential equation is

$$ω ( t ) = \frac{1}{B} ln ( \sqrt{\frac{B π}{2 C}} {Ae}^{\frac{{BD}^{2}}{2 C}} ) + \frac{1}{B} ln ( erf ( \sqrt{\frac{B}{2 C}} ( Ct - D ) ) + K ) + \frac{C}{2} {t}^{2} - D t \qquad ( 2.2 )$$

with substitutions

$$C = \frac{3}{2} ψ p \frac{h}{J} and D = \frac{{M}_{R}}{J}$$

In another preferred embodiment of the invention, the measured data is fitted to a velocity profile with equations

$$ω ( t ) = \frac{1}{B} ln ( \sqrt{\frac{B π}{2 C}} ( D - {Ct}_{0} ) {e}^{\frac{{BD}^{2}}{2 C}} ) + \frac{1}{B} ln ( erf ( \sqrt{\frac{B}{2 C}} ( Ct - D ) ) + {K}_{0} ) + \frac{C}{2} {t}^{2} - Dt \qquad ( 2.7 )$$

$$with$$

$${K}_{0} = exp ( ( {Dt}_{0} - \frac{C}{2} {t}_{0}^{2} - \frac{1}{B} ln ( \sqrt{\frac{B π}{2 C}} ( D - {Ct}_{0} ) {e}^{\frac{{BD}^{2}}{2 C}} ) ) B ) - erf ( \sqrt{\frac{B}{2 C}} ( {Ct}_{0} - D ) ) \qquad ( 2.8 )$$

wherein K is the integration constant and boundary conditions are

0=Ct₀−D+A (2.5)

A=D−Ct₀ (2.6)

The invention is also directed at an electric motor system according to claim 10. The electric motor system comprises an electric motor and a frequency converter or drive. The electric motor system is provided for carrying out a method according to any of claims 1 to 9.

### BRIEF DESCRIPTION OF THE DRAWINGS

Further details and advantages of the invention are described with reference to the figures. The figures show:

FIG. 1: graph showing measurement of a linear current ramp;

FIG. 2. power law fit after a set of measurements;

FIG. 3: flow chart of the underlying algorithm of the presented invention;

FIG. 4: thin flywheel for testing the underlying algorithm of the invention;

FIG. 5: test results with according Gauss fits;

FIG. 6: details of the test results with small moments of inertia;

FIG. 7: test results for thick flywheel;

FIG. 8: test results for thick flywheel; and

FIG. 9: test results for thick flywheel and dynamic friction.

### DETAILED DESCRIPTION

The presently described method for inertia measurement of an electric motor and its associated system is based on the direct acceleration of the motor. The moment of inertia is the proportionality factor between the desired acceleration and the imposed torque

\vec{M}=J·\vec{α} (1.1)

The torque itself is directly proportional to the current component orthogonal to the magnetic flux of the rotor magnet i_{q}. The according relation reads

$$\vec{M} = \frac{3}{2} ψ p {i}_{q} \qquad ( 1.2 )$$

with the permanent magnetic flux ψ (“back-EMF constant”) and the number of pole pairs p.

In general, there are two main components affecting the mechanical dynamics of the system, the force of friction and the static friction. While the former adds a constant torque M_{R} to the motion, the latter just locks the motor in standstill until a threshold torque M_{H} is reached. Both effects influence any measurement where one wants to measure the acceleration of the system when a constant current is imposed. It is noteworthy that M_{R} is an unknown which is not directly accessible and which directly adds to the electrical torque of the system.

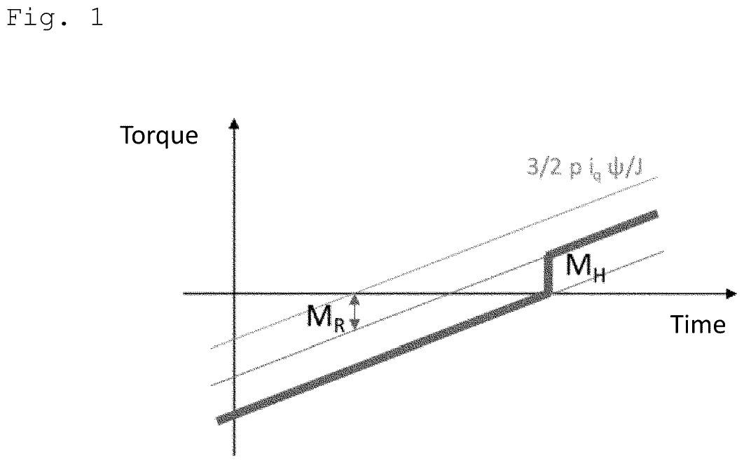

The present invention proposes a linear current ramp instead where the constant acceleration of the friction is decoupled from the linear acceleration of the electrical torque. The general idea is depicted in FIG. 1.

The differential equation describing the mechanical system is

$$\frac{d}{dt} ω = \frac{3}{2} ψ p \frac{{i}_{q}}{J} - \frac{{M}_{R}}{J} - \frac{{M}_{H}}{J} \qquad ( 1.3 )$$

where M_{H} only acts while ω=0. As the current is ramped linearly, i_{q} is put to be i_{q}=h(t−t₀), which leads to a solution of the differential equation (for ω>0) of

$$ω = \frac{3}{4} ψ p h \frac{{t}^{2}}{J} - ( \frac{3}{2} ψ {pht}_{0} + {M}_{R} ) \frac{t}{J} + K \qquad ( 1.4 )$$

The integration constant K is used to evaluate the impact of M_{H}. Static friction acts until the total acceleration becomes positive, thus

$$\frac{d}{d t} ω > 0$$

which happens at

$$t = {t}_{0} + \frac{2}{3} \frac{{M}_{R}}{p h ψ} + \frac{2}{3} \frac{{M}_{H}}{p h ψ}$$

At the same point ω=0, which is used to calculate C to be

$$C = - \frac{{M}_{H}^{2}}{3 Jph ψ} + {( \frac{1}{2} \sqrt{\frac{3 p h ψ}{J}} {t}_{0} + \frac{{M}_{R}}{\sqrt{3 Jph ψ}} )}^{2} \qquad ( 1.5 )$$

The complete measurement process of the method may consist of two steps, the single ramp to get a result for the moment of inertia for a specific slope h, and a power law fit to find the real value of the moment of inertia. A single ramp is executed by choosing a slope h and calculating a guess for the moment of inertia by fitting the velocity profile with a quadratic equation

f(x)=ax²+bx+c

Using the solution of the system equation, the moment of inertia is calculated as

$$J = \frac{3}{4} ψ h p \frac{1}{a} \qquad ( 1.6 )$$

Similarly, the remaining fit parameters can be used to get estimates for the friction as

$${M}_{R} = - \frac{3}{2} ψ {hpt}_{0} - bJ \qquad ( 1.7 )$$

$$and$$

$${M}_{H} = \vert \sqrt{{( \frac{3}{2} ψ {hpt}_{0} + {M}_{R} )}^{2} - c \cdot 3 J ψ h p} \qquad ( 1.8 )$$

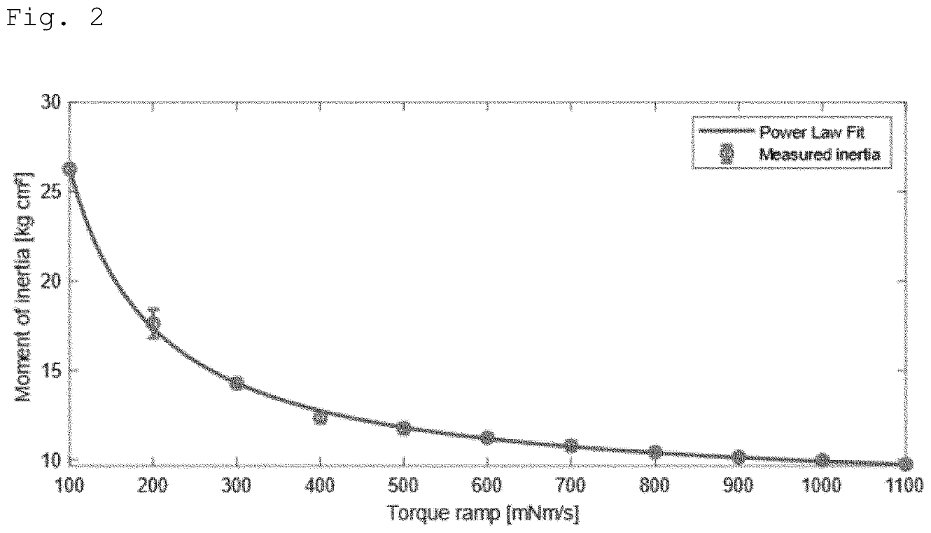

FIG. 2 shows the results of the inertia measurements using different current slopes. They monotonically decrease with increasing slopes. On a closer look, they decrease according to the power law f(x)=ax^{b}+c. Therefore, to conclude the inertia measurement, several ramps (at least three) need to be performed and the results fit with the power law. The resulting offset c is recognized as the real value of the moment of inertia, as it compensates all the effects leading to wrong results at smaller slopes. It can be observed that the best results can be obtained by choosing appropriate slopes to perform the measurements. These depend on the maximal current i_{q,max} at the end of the ramp. It is recommended to choose slopes where this maximal current is between 20% and 80% of the rated current of the motor. Within this range, one should choose slopes, which are evenly distributed. A good estimate can be obtained by using the relation

i_{q,max}=k\sqrt{h}+l (1.9)

and calculating k and l using two random measurements.

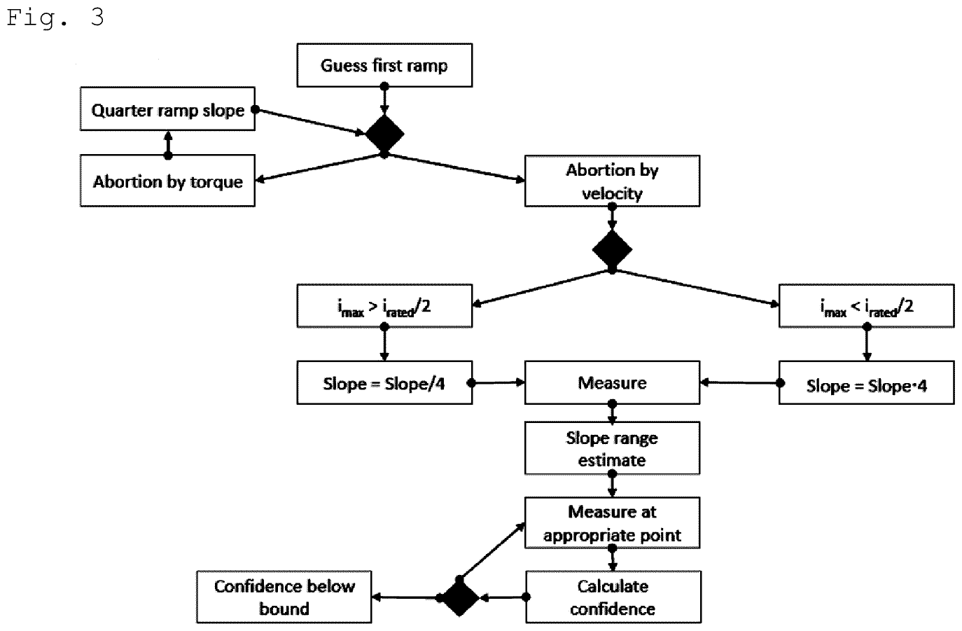

FIG. 3 shows a flowchart of the algorithm. It basically includes both measurement steps described above. It is supplemented by an introductory step where the first slope is guessed. If it is too steep, i.e. if the maximal current is reached before the desired velocity is reached, the slope is reduced by quartering it until it works.

At the end of the algorithm, the confidence bounds of the fitted moment of Inertia are calculated. The confidence bounds are used as a final measure to estimate whether a trustworthy result has been obtained, or whether another measurement is necessary. At a maximum number of 20 measurements, the algorithm is stopped using the result as it takes into account also the final confidence bounds.

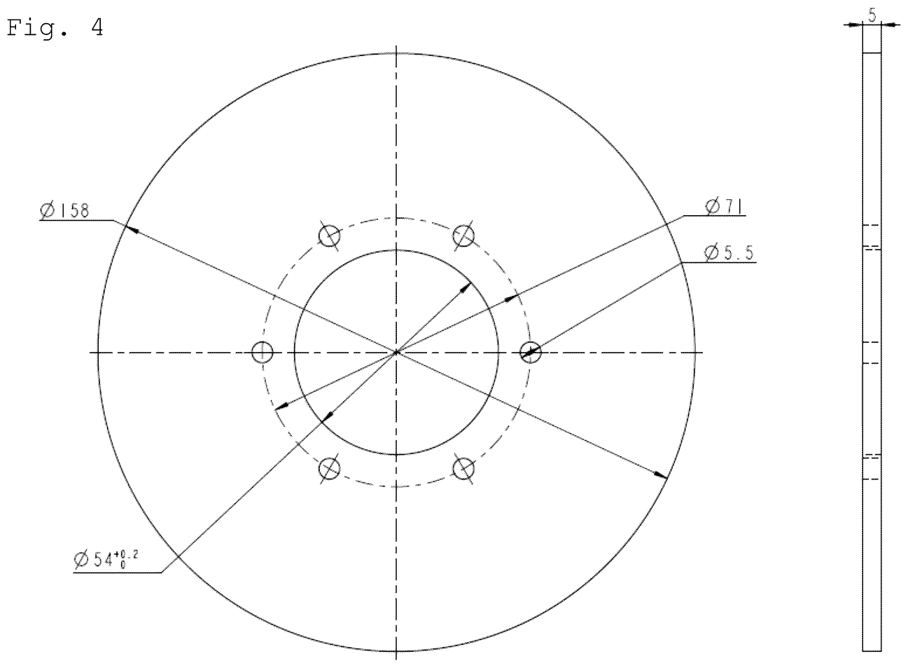

The algorithm can be tested and used with e.g. an AKM44E motor with an adapter for flywheels with known moments of inertia. Generally, the algorithm can be tested with any electric motor type such as e.g. PMSM-SPM. The wheel is depicted in FIG. 4. In the presently given example, two different sized wheels may have a mass of m₁=0.67 kg and m₂=1.008 kg. A thinner flywheel may have a width of 5 mm while a thick one has 7.5 mm.

The moments of inertia of the adapter, thin and thick flywheel and the screws used to attach them are known. Those are Jₐ=0.00044 kgm², J₁=0.00236 kgm², J₂=0.00353 kgm² and Jₛ=0.000038 kgm², in the same order. However, a careful calculation of the moments of inertia of the both flywheels has also been made based on the formula of

$$J = m \frac{{r}_{i}^{2} + {r}_{o}^{2}}{2}$$

with the inner radius rᵢ and the outer radius r₀. Considering the holes for the screws, this formula yields J₁=0.002335 kgm² and J₂=0.00350 kgm² for the two flywheels. The motor itself has a moment of inertia of Jₘ=0.00027 kgm² obtained from its data sheet. Four cases are considered as follows:

| | | Data sheet value | Calculated value |
|---|---|---|---|
| Case | Setup | [kg cm²] | [kg cm²] |
| 1 | Adapter only | 7.10 | 7.10 |
| 2 | Adapter with screws | 7.48 | 7.48 |
| 3 | Thin flywheel | 31.08 | 30.83 |
| 4 | Thick flywheel | 42.78 | 42.50 |

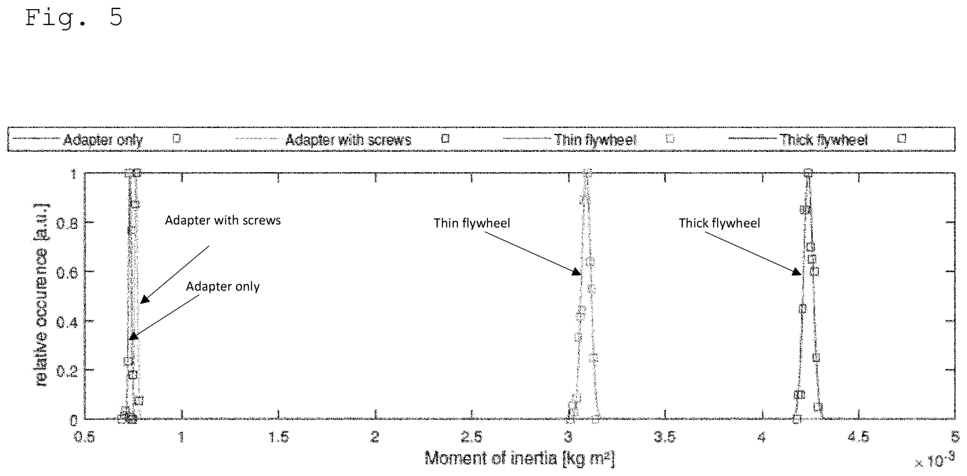

The test was carried out with some 100 measurements for each case for providing statistically reliable data. The results are shown in FIG. 5. The scale for the moment of inertia is discreticized each 0.05 kg m². The test establishes how often each of the slots of the scale has been measured and fits the result with a Gaussian distribution. The results are also shown in the following table:

| | | Measured value | Standard deviation |
|---|---|---|---|
| Case | Setup | [kg cm²] | [kg cm²] |
| 1 | Adapter only | 7.335 | 0.059 |
| 2 | Adapter with screws | 7.655 | 0.074 |
| 3 | Thin flywheel | 30.92 | 0.23 |
| 4 | Thick flywheel | 42.40 | 0.24 |

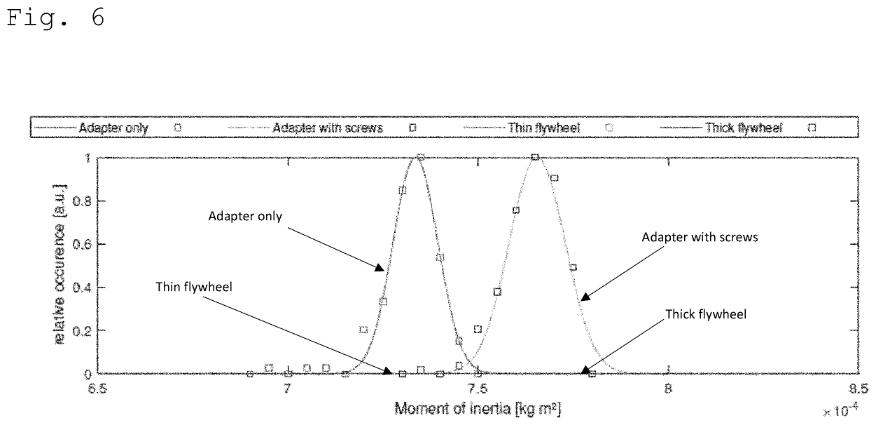

The statistical error from the standard deviation of the captures measurements is indicated to be below 1%. In comparison to the theoretical values, the measurement results deviate in the regime of uncertainty between the data sheet values and the calculated values. Some information on the precision of the given values as well as of the given values used in the measurement process is missing, namely the back-EMF constant. Still, the measurement compares well with the given theoretical values showing not only the good precision of the measurement process, but also a good accuracy. As shown in FIG. 6, the moment of inertia of only the adapter attached to the motor and the adapter with six screws added to it can be clearly distinguished.

These statistical considerations can serve as a guideline on how to use the measurement and on what can be expected of it. The applicability, in the end, depends clearly on the use case in which inertia measurement is intended to be used. Under certain circumstances, the approach as a whole might not be suitable. For these cases, other measurement principles might have to be applied.

The presently described invention may be extended in certain circumstances. The inclusion of a tight shaft sealing may affect the dynamic friction of the entire system in such a drastic way that the resulting dynamics from a linear current ramp cannot be described in a reliable way by a quadratic velocity response. Detailed investigations show a velocity dependence of the dynamic friction, which can be described by some good approximation by an exponential function. This observation leads to the extension of the mechanical model to the differential equation

$$\frac{d}{dt} ω = \frac{3}{2} ψ p \frac{ht}{J} - ( \frac{{M}_{R}}{J} - {Ae}^{- B ω ( t )} ) \qquad ( 2.1 )$$

with some unknown factors A and B. For simplicity, the substitutions C= 3/2ψph/J and D=MRJ can be used. With the help of a computer algebra system, the general solution of this differential equation is found to be

$$ω ( t ) = \frac{1}{B} ln ( \sqrt{\frac{B π}{2 C}} {Ae}^{\frac{{BD}^{2}}{2 C}} ) + \frac{1}{B} ln ( erf ( \sqrt{\frac{B}{2 C}} ( Ct - D ) ) + K ) + \frac{C}{2} {t}^{2} - Dt \qquad ( 2.2 )$$

with the integration constant K. The integration constant can be used to get a condition for the real root t0 of the function. For this, the condition

ω(t0)=0 (2.3)

can be used to obtain

$$0 = \frac{1}{B} ln ( \sqrt{\frac{B π}{2 C}} {Ae}^{\frac{{BD}^{2}}{2 C}} ) + \frac{1}{B} ln ( erf ( \sqrt{\frac{B}{2 C}} ( {Ct}_{0} - D ) ) + K ) + \frac{C}{2} {t}_{0}^{2} - {Dt}_{0}$$

$$( {Dt}_{0} - \frac{C}{2} {t}_{0}^{2} - \frac{1}{B} ln ( \sqrt{\frac{B π}{2 C}} {Ae}^{\frac{{BD}^{2}}{2 C}} ) ) B = ln ( erf ( \sqrt{\frac{B}{2 C}} ( {Ct}_{0} - D ) ) + K )$$

$$K = exp ( ( {Dt}_{0} - \frac{C}{2} {t}_{0}^{2} - \frac{1}{B} ln ( \sqrt{\frac{B π}{2 C}} {Ae}^{\frac{{BD}^{2}}{2 C}} ) ) B ) - erf ( \sqrt{\frac{B}{2 C}} ( {Ct}_{0} - D ) ) .$$

This function is directly applicable to describe the velocity response from a constant current amp with an exponential velocity dependent dynamic friction. Exhausting testing has shown, however, that the small velocity behaviour induces more insecurities such that another restriction has been put into place, with the disadvantage of cutting off the first tip of the velocity profile and considering only the regime where an influence of the static friction can be neglected.

For this additional restriction, the presently employed model states:

\dot{ω}Ct−(D−Ae^{-Bω}) (2.4)

For a negligible static friction, one expects

\dot{ω}(t₀)=0

and

ω(t₀)=0

0=Ct0−D+A (2.5)

A=D−Ct0 (2.6)

With this condition the final velocity profile can be obtained:

$$ω ( t ) = \frac{1}{B} l \vert n ( \sqrt{\frac{B π}{2 C}} ( D - {Ct}_{0} ) {e}^{\frac{{BD}^{2}}{2 C}} ) + \frac{1}{B} ln ( erf ( \sqrt{\frac{B}{2 C}} ( Ct - D ) ) + {K}_{0} ) + \frac{C}{2} {t}^{2} - Dt , \qquad ( 2.7 )$$

$$with$$

$${K}_{0} = exp ( ( {Dt}_{0} - \frac{C}{2} {t}_{0}^{2} - \frac{1}{B} ln ( \sqrt{\frac{B π}{2 C}} ( D - {Ct}_{0} ) {e}^{\frac{{BD}^{2}}{2 C}} ) ) B ) - erf ( \sqrt{\frac{B}{2 C}} ( {Ct}_{0} - D ) ) . \qquad ( 2.8 )$$

Thus, a function with four unknowns is obtained, which can be solved by fitting a velocity profile with the presently employed model.

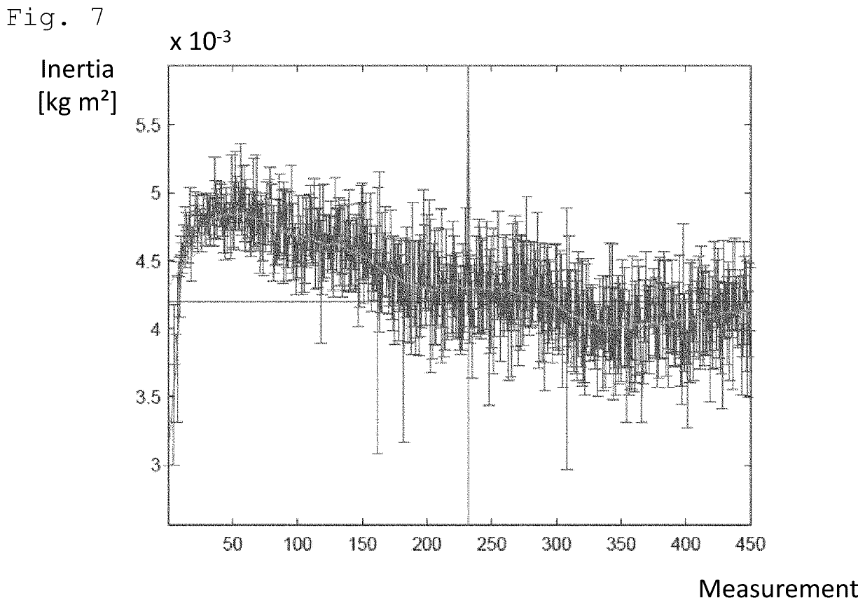

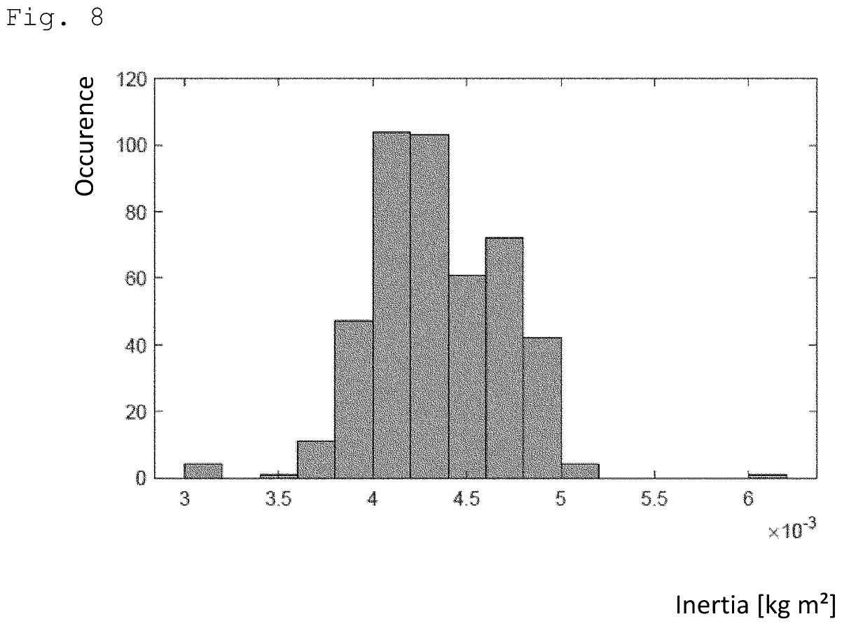

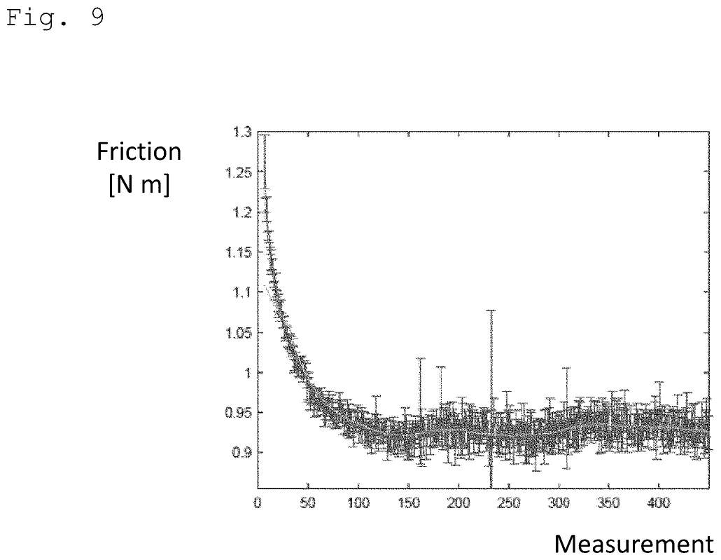

FIGS. 7 to 9 document further testing of the presently described invention, whereby 300 fitting cycles have been used and the final sum of residuals has been tracked to get an estimate on the quality of the fit.

The current has been ramped up with a constant slope of h=0.11 A/s. The fit was obtained for 64 measured points between 20% and 95% of the nominal velocity.

The shown results were obtained for a run of 500 consecutive measurements, starting with a cold motor and using the thick flywheel. The results show some overshoot for intermediate temperatures at the beginning of the test. When the system reached its steady state temperature, a flattening of the curve in the expected regime of J=42 kgcm² is shown. The real value lies well within the error bars. The parameters and steps described with reference to the possible tests may represent features of the presently described invention.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A method for measuring mechanical system parameters, in particular the moment of inertia and friction effects, describing an electric motor system, the method comprising the steps of
applying a linear ramp of electrical torque corresponding to a current slope h to the system,
measuring data representative of the velocity response of the system,
fitting the measured data with a model function by applying a curve fitting algorithm, wherein a number of fitting parameters coincides with the mechanical system parameters of the system.

2. The method according to claim 1, wherein the linear ramp of electrical torque is applied by ramping an input current from zero to a motor specific maximum.

3. The method according to claim 1, wherein the model function describing the mechanical system parameters is:
$$\frac{d}{dt} ω = \frac{3}{2} ψ p \frac{{i}_{q}}{J} - \frac{{M}_{R}}{J} - \frac{{M}_{H}}{J} \qquad ( 1.3 )$$
wherein the force of friction and the static friction of the mechanical system yield a constant torque M_{R} and a threshold torque M_{H}, respectively.

4. The method according to claim 1, wherein the current slope h is chosen for a single ramp and a guess for the moment of inertia of the mechanical system is calculated by fitting the measured data with a quadratic equation f(x)=ax²+bx+c.

5. The method according to claim 3, wherein the moment of inertia is calculated from equation
$$J = \frac{3}{4} ψ hp \frac{1}{a} \qquad ( 1.6 )$$

6. The method according to claim 3, wherein the force of friction and the static friction of the mechanical system yield a constant torque M_{R} and a threshold torque M_{H} calculated from equations
$${M}_{R} = - \frac{3}{2} ψ {hpt}_{0} - bJ \qquad ( 1.7 )$$
$$and$$
$${M}_{H} = \vert \sqrt{{( \frac{3}{2} ψ {hpt}_{0} + {M}_{R} )}^{2} - c \cdot 3 J ψ hp} \qquad ( 1.8 )$$

7. The method according to claim 3, wherein the method is repeated with at least three different current slopes h, wherein the results are fitted with the power law f(x)=ax^{b}+c and the resulting offset c is the real value of the momentum of inertia.

8. The method according to claim 1, wherein the model function describing the mechanical system parameters is
$$\frac{d}{dt} ω = \frac{3}{2} ψ p \frac{ht}{J} - ( \frac{{M}_{R}}{J} - {Ae}^{- B ω ( t )} ) \qquad ( 2.1 )$$
wherein the force of friction of the mechanical system yields a constant torque M_{R} and wherein the general solution of this differential equation is
$$ω ( t ) = \frac{1}{B} ln ( \sqrt{\frac{B π}{2 C}} {Ae}^{\frac{{BD}^{2}}{2 C}} ) + \frac{1}{B} ln ( erf ( \sqrt{\frac{B}{2 C}} ( Ct - D ) ) + K ) + \frac{C}{2} {t}^{2} - Dt \qquad ( 2.2 )$$
with substitutions
$$C = \frac{3}{2} ψ p \frac{h}{J} and D = \frac{{M}_{R}}{J}$$

9. The method according to claim 8, wherein the measured data is fitted to a velocity profile with equations
$$ω ( t ) = \frac{1}{B} ln ( \sqrt{\frac{B π}{\vert 2 C}} ( D - {Ct}_{0} ) {e}^{\frac{{BD}^{2}}{2 C}} ) + \frac{1}{B} ln ( erf ( \sqrt{\frac{B}{2 C}} ( Ct - D ) ) + {K}_{0} ) + \frac{C}{2} {t}^{2} - Dt \qquad ( 2.7 )$$
$$with$$
$${K}_{0} = exp ( ( {Dt}_{0} - \frac{C}{2} {t}_{0}^{2} - \frac{1}{B} ln ( \sqrt{\frac{B π}{2 C}} ( D - {Ct}_{0} ) {e}^{\frac{{BD}^{2}}{2 C}} ) ) B ) - \qquad ( 2.8 )$$
$$erf ( \sqrt{\frac{B}{2 C}} ( {Ct}_{0} - D ) )$$
wherein K is the integration constant and boundary conditions are
0=Ct₀−D+A (2.5)
A=D−Ct₀ (2.6)

10. An electric motor system comprising an electric motor and a frequency converter or drive, wherein the electric motor system is provided for carrying out the method according to claim 1.

11. The method according to claim 2, wherein the model function describing the mechanical system parameters is:
$$\frac{d}{dt} ω = \frac{3}{2} ψ p \frac{{i}_{q}}{J} - \frac{{M}_{R}}{J} - \frac{{M}_{H}}{J} \qquad ( 1.3 )$$
wherein the force of friction and the static friction of the mechanical system yield a constant torque M_{R} and a threshold torque M_{H}, respectively.

12. The method according to claim 2, wherein the current slope h is chosen for a single ramp and a guess for the moment of inertia of the mechanical system is calculated by fitting the measured data with a quadratic equation f(x)=ax²+bx+c.

13. The method according to claim 3, wherein the current slope h is chosen for a single ramp and a guess for the moment of inertia of the mechanical system is calculated by fitting the measured data with a quadratic equation f(x)=ax²+bx+c.

14. The method according to claim 4, wherein the moment of inertia is calculated from equation
$$J = \frac{3}{4} ψ hp \frac{1}{a} \qquad ( 1.6 )$$

15. The method according to claim 4, wherein the force of friction and the static friction of the mechanical system yield a constant torque M_{R} and a threshold torque M_{H} calculated from equations
$${M}_{R} = - \frac{3}{2} ψ {hpt}_{0} - bJ \qquad ( 1.7 )$$
$$and$$
$${M}_{H} = \vert \sqrt{{( \frac{3}{2} ψ {hpt}_{0} + {M}_{R} )}^{2} - c \cdot 3 J ψ hp} \qquad ( 1.8 )$$

16. The method according to claim 5, wherein the force of friction and the static friction of the mechanical system yield a constant torque M_{R} and a threshold torque M_{H} calculated from equations
$${M}_{R} = - \frac{3}{2} ψ {hpt}_{0} - bJ \qquad ( 1.7 )$$
$$and$$
$$M = \vert \sqrt{{( \frac{3}{2} ψ {hpt}_{0} + {M}_{R} )}^{2} - c \cdot 3 J ψ hp} \qquad ( 1.8 )$$

17. The method according to claim 4, wherein the method is repeated with at least three different current slopes h, wherein the results are fitted with the power law f(x)=ax^{b}+c and the resulting offset c is the real value of the momentum of inertia.

18. The method according to claim 4, wherein the method is repeated with at least three different current slopes h, wherein the results are fitted with the power law f(x)=ax^{b}+c and the resulting offset c is the real value of the momentum of inertia.

19. The method according to claim 5, wherein the method is repeated with at least three different current slopes h, wherein the results are fitted with the power law f(x)=ax^{b}+c and the resulting offset c is the real value of the momentum of inertia.

20. The method according to claim 6, wherein the method is repeated with at least three different current slopes h, wherein the results are fitted with the power law f(x)=ax^{b}+c and the resulting offset c is the real value of the momentum of inertia.
